(19) United States
(12) Patent Application Publication
(10) Pub. No.: US 2024/0249939 A1
(43) Pub. Date: Jul. 25, 2024

(54) DIAMOND DEVICE OR STRUCTURE AND METHOD FOR PRODUCING A DIAMOND DEVICE OR STRUCTURE

(71) Applicant: ECOLE POLYTECHNIQUE FEDERALE DE LAUSANNE (EPFL), Lausanne (CH)

(72) Inventors: Reza SOLEIMAN ZADEH ARDEBILI, Pully (CH); Mehdi NAAMOUN, Lausanne (CH); Elison de Nazareth MATIOLI, Lausanne (CH)

(21) Appl. No.: 18/566,563

(22) PCT Filed: Jun. 3, 2021
(86) PCT No.: PCT/IB2021/054876

§ 371 Date: Dec. 1, 2023

(51) Int. Cl. H01L 21/02; C01B 32/25; C23C 16/27

(52) U.S. Cl. CPC H01L 21/02645; C01B 32/25; C23C 16/27; H01L 21/02389; H01L 21/02527; C01P 2002/82; C01P 2002/85; C01P 2004/03

(57) ABSTRACT

The present invention concerns a diamond device or structure comprising at least one supporting layer or material including at least one or a plurality of support structures inside the at least one supporting layer or material; a plurality of recesses defined by the at least one or the plurality of support structures; and at least one diamond micro-seed and a plurality of diamond nano-seeds located in each recess or in the plurality of recesses.

### FIELD OF THE INVENTION

The present invention relates to diamond devices and structures and methods for producing diamond devices and structures. The present invention relates in particular to diamond devices and structures comprising diamond seeding and a seed dibbling method for the growth of high-quality diamond. Such diamond devices or structures can be used, for example, in electronic devices and integrated circuits (ICs), diamond heat spreaders, near junction heat spreaders as well as jewelry, mechanical components, optical and photonic devices, sensors and detectors, biomedical devices and cutting/machining tools.

### BACKGROUND

The integration of diamond and GaN has been highly pursued for thermal management purposes as well as combining their exceptional complementary properties for power electronics applications and novel semiconductor heterostructures. However, the growth of diamond on GaN is challenging due to the high lattice and thermal expansion mismatches. The weak adhesion of diamond to GaN and high residual stresses after the deposition often result in the diamond film delamination or development of cracks, which prevents the subsequent device fabrication.

Diamond has been regarded as a potentially excellent material for power electronics applications due to excellent properties such as high thermal conductivity, wide bandgap, large breakdown field, and high hole mobility¹. On the other hand, GaN is also a wide bandgap semiconductor with large critical electric field, high electron mobility and saturation velocity, and with large-scale fabrication capabilities on the cost-effective GaN-on-Si wafers².

The high thermal conductivity of diamond films^{3,4} has been utilized as heat spreaders for the thermal management of GaN power electronic devices and demonstrated remarkable reduction of thermal resistances and elimination of the hot spots and temperature gradients from both GaN high electron mobility transistors (HEMTs)⁵⁻¹⁰ as well as vertical GaN devices¹¹. Moreover, while high performance n-type GaN devices such as HEMTs with low resistance and high voltage capabilities are currently used in many power electronics applications¹², the performance of p-type GaN is still limited, mainly due to the low hole mobility and poor activation of Mg dopants in GaN¹³. On the other hand, diamond has excellent properties for p-type power electronic devices with high hole concentrations and mobilities but still lacks shallow level n-type dopants¹⁴. The integration of diamond with GaN can open new possibilities for novel devices and integrated circuits (ICs) combining the complementary properties of diamond as p-type, and GaN as n-type semiconductors.

Different strategies have been suggested for the diamond-GaN integration and the most common approach is the integration of GaN on diamond substrates¹⁵⁻¹⁷. However, because of the small size of available diamond substrates and their high cost, GaN-on-diamond substrates might be used only for the high-end applications².

A lower cost approach has been proposed by integrating diamond on the cost-effective GaN-on-Si substrates, on which diamond transistors were demonstrated on AlGaN/GaN-on-Si substrates with excellent device characteristics, even without polishing of the rough diamond surfaces¹⁸. However, the high roughness of as-grown diamond imposes limitations for the wafer processing using planar fabrication methods. Therefore, polishing is an essential step to obtain smooth diamond surfaces and reliable fabrication processes. However, due to the mismatches of the coefficients of thermal expansion (CTE) between diamond and GaN (28% mismatch)¹⁹, the CVD diamond films can develop high residual stresses during growth (>1.5 GPa)²⁰. Due to the rather weak attachment of the diamond to GaN, such high residual stresses can result in delamination or cracking of the film, and the diamond films cannot sustain the high mechanical stresses of the polishing steps.

The weak attachment of diamond to GaN, mainly via weak van der Waals interactions²¹, and the presence of high stresses in the film have been serious issues making the diamond film prone to delamination^{20,22}. Currently the low-stress high-adhesion growths of diamond on GaN and its polishing has remained as a big challenge.

Some studies have proposed the use of AlN, SiN or SiC interlayers to improve the adhesion, owing to the formation of strong covalent carbide bonds²³⁻²⁶, which can also protect GaN from decomposition in the CVD reactors at temperatures above 600° C. under hydrogen plasmas 2. However, the presence of extra thin films between GaN and diamond can introduce high thermal boundary resistances (TBRs) and limit the heat conduction²⁷.

The diamond seeding step before the growth can also affect the quality of the diamond film, grain size, thermal conductivity and TBRs^{28,29}. A high density seeding of the substrate using diamond nanoseeds at densities above 10¹¹ cm⁻² can initiate a fast growth and diamond film coalescence, which could minimize the decomposition of GaN in the hydrogen plasma environment and thus improve the adhesion³⁰. A recent study has experimented mixed-sized diamond seeding using microseeds and nanoseeds to grow CVD diamond films on GaN and AlN³¹. However, diamond growth on GaN was unsuccessful due to its poor adhesion.

### SUMMARY OF THE INVENTION

The present invention addresses the above-mentioned limitations by providing a diamond device or structure according to claim 1 and a method for producing a diamond device or structure according to claim 48.

Other advantageous features can be found in the dependent claims.

The diamond device or structure and the method for producing a diamond device or structure of the present disclosure solves the above-mentioned problems relating to the adhesion of diamond to underlying layers and/or substrates.

In particular, improved adhesion to, for example, GaN is assured.

While diamond adhesion to GaN is of particular importance, it is nevertheless shown herein as a proof-of-concept of the present invention and the diamond device or structure and the method for producing a diamond device or structure of the present disclosure are not limited to assuring improved adhesion to solely GaN but are equally applicable for diamond adhesion to other material or materials.

Here, a method for producing a diamond device or structure is presented that is a seed dibbling method for efficient seeding and growth of diamond on foreign substrates, for example GaN-on-Si, which enables the growth of high-quality diamond films with large grains, low residual stress and excellent adhesion to the substrate. This method relies on the micro structuration of the substrate and seeding using both micro- and nano-seeds. The seed dibbling method provides diamond devices and structures addressing the issues of diamond film delamination after the growth and enables a reliable polishing of diamond films grown on, for example, GaN substrates to obtain smooth diamond-on-GaN substrates.

Advantageously, the seed dibbling method for seeding and growing or depositing high-quality diamond films may be performed, for example, on cost-effective GaN-on-Si substrates. Exemplary high-quality diamond films grown on GaN-on-Si presented, for example, 95% sp³/sp² ratio, significantly larger grains and lower residual stresses (as low as 0.2 GPa) compared to conventional methods.

This method is not limited only to the growth of high-quality diamond and can be used to grow other quality diamond and other stresses, as well as single crystalline, polycrystalline, microcrystalline, nanocrystalline and ultra-nanocrystalline films, with or without presence of (points and/or extended) defects, impurities, and dopants in the material.

Moreover, the excellent adhesion obtained by this method enabled a reliable polishing of the as-grown diamond films on, for example, GaN-on-Si without any delamination, resulting in smooth diamond-on-GaN substrates, for example, with sub-nanometer root mean square roughness. This method opens many new possibilities for the development of high-performance power electronic devices and other electronic devices, integrated devices, and heterostructure devices with excellent thermal management based on a diamond-on-GaN platform.

In addition, the method is not limited to GaN-on-Si substrates and is extendable to other substrates or materials to combine the outstanding properties of diamond with other kinds of devices.

For example, the method can be used for the deposition of a diamond layer or material on micro-mechanical parts such as, but not limited to, (micro-)mechanical components, cutting tools made of different materials such as, and not limited to, steel, stainless steel, sapphire, borosilicate, quartz, alumina, tungsten carbide. This method of the present disclosure can also be used for the deposition of diamond layer or material on sensors and/or biosensors, detectors and/or bio-detectors made of different kinds of materials.

The method of the present disclosure can also assure the deposition of diamond layer or material forming and/or creating a photonic platform of different kinds of materials. This method of the present disclosure can also assure the deposition of diamond layer or material forming and/or creating color-center such as NV-centers arrays on different kind of materials.

The method of the present disclosure can also be used for the deposition of diamond with different semiconducting behaviors including intrinsic, undoped, un-intentionally doped, doped (n- and/or p-type) diamond layers with different doping concentrations. This method can be used to assure the deposition of diamond with different thermal conductivity, for example between 50 W/m·K to 3000 W/m·K, for thermal management applications.

The method of the present disclosure can also be used for the deposition of diamond layer or material by different CVD deposition methods such as, but not limited to, plasma enhanced (or Microwave Plasma) CVD, low temperature plasma CVD, atmospheric plasma CVD, plasma torch and hot filament CVD.

The above and other objects, features, and advantages of the present invention and the manner of realizing them will become more apparent, and the invention itself will best be understood from a study of the following description with reference to the attached drawings showing some preferred embodiments of the invention.

### A BRIEF DESCRIPTION OF THE SEVERAL VIEWS OF THE DRAWINGS

FIGS. 1A to 1C schematically show aspects of an exemplary diamond device or structure according to the present disclosure.

FIGS. 1D to 1E schematically show an exemplary embodiment of a diamond device or structure according to the present disclosure.

FIG. 2A shows a schematic diagram of an exemplary diamond devices or structures fabrication using a method according to the present disclosure. The method may comprise some or all of the exemplary steps of: I. Providing at least one supporting layer or material, for example, a GaN-on-Si substrate, II. Etching of holes in the substrate, III. Seed dibbling using both nanoseeds and microseeds of diamond, IV. (CVD) diamond growth, and V. diamond polishing.

FIG. 2B is an optical microscope image of the exemplary GaN-on-Si substrate structured and seeded by the seed dibbling method of the present disclosure. FIG. 2C is a higher magnification image showing microseeds effectively positioned inside the dibbled substrate.

FIG. 2D is a SEM image of the high-density coverage of the nanoseeds on the entire substrate surface.

FIGS. 3A to 3D show cross-sectional SEM images of samples with high aspect ratio seed dibbling with the opening widths of (A) 4 μm, (B) 10 μm, (C) 20 μm and (D) 50 μm; FIG. 3E is a SEM image of the sample with 4 μm holes/openings, showing the entrapment of microseeds in the entire depth of the holes, while only a section of length of (approximately) 5 μm from the opening or top part of the hole contributed to the growth of diamond; and FIG. 3F is a zoomed-in picture of the dashed area in FIG. 3E, showing the contribution of both the microseeds and nanoseeds to the diamond growth.

FIG. 4A is a cross-sectional SEM image of the diamond film grown on an exemplary AlGaN/GaN-on-Si substrate using an optimized seed dibbling method of the present disclosure. The inset shows a dibbled region filled with diamond, where the initial microseeds are distinguishable, and FIG. 4B is a High-resolution XRT image of the substrate of FIG. 4A, where the materials are labeled in gray scale based on the X-ray transmittance and some regions are hidden to form a cut-view image, revealing an effective seed dibbling and diamond growth without any voids.

FIG. 5A shows the stress profile along the diamond film thickness produced by seed dibbling using different seeds. FIG. 5B shows phase purity (sp³/sp² ratio) of carbon bonds and FIG. 5C shows a Full width at half maximum (FWHM) of the peak corresponding to diamond in the Raman spectrum. FIG. 5D shows X-ray photoelectron spectroscopy (XPS) data of the diamond surface, the inset shows the spectra of the oxygen atoms. FIG. 5E is a SEM image of a diamond film grown on a chip with a region seeded with mixed seed dibbling and a region with only nanoseeds without seed dibbling.

FIGS. 6A and 6B show respectively top view and cross-sectional SEM images of the as-grown diamond and the diamond after diamond polishing. FIG. 6C shows an atomic force microscope image of the polished diamond surface with root mean square roughness R_{q}=0.6 nm. FIG. 6D shows AlGaN/GaN-on-Si chips with diamond film reliably grown on top of them using the seed dibbling method of the present disclosure and polished to obtain smooth and transparent diamond surfaces. FIG. 6E is a Raman spectrum of the diamond surface before and after polishing showing no significant changes.

Herein, identical reference numerals are used, where possible, to designate identical elements that are common to the Figures.

### DETAILED DESCRIPTION OF SEVERAL EMBODIMENTS

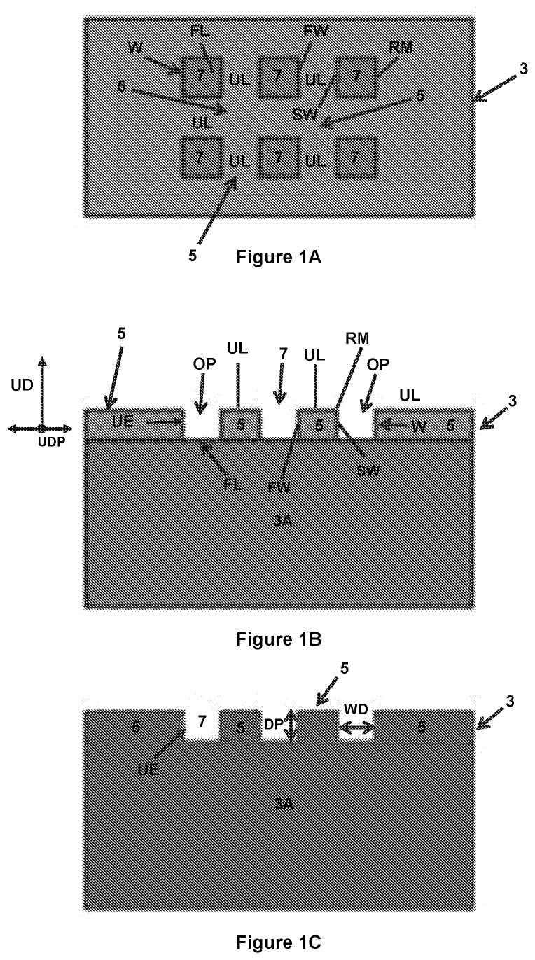

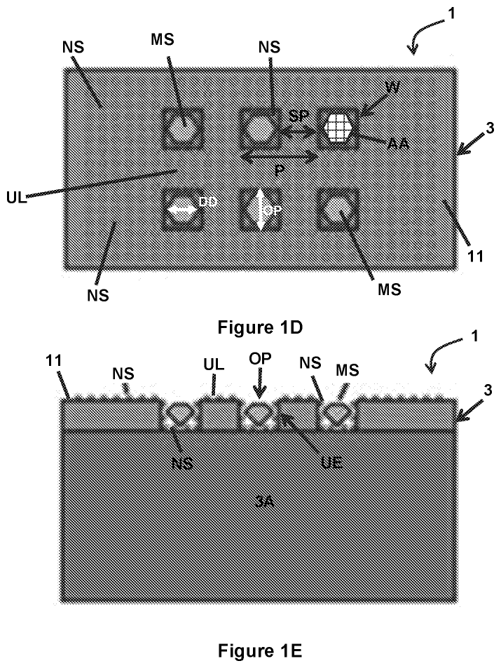

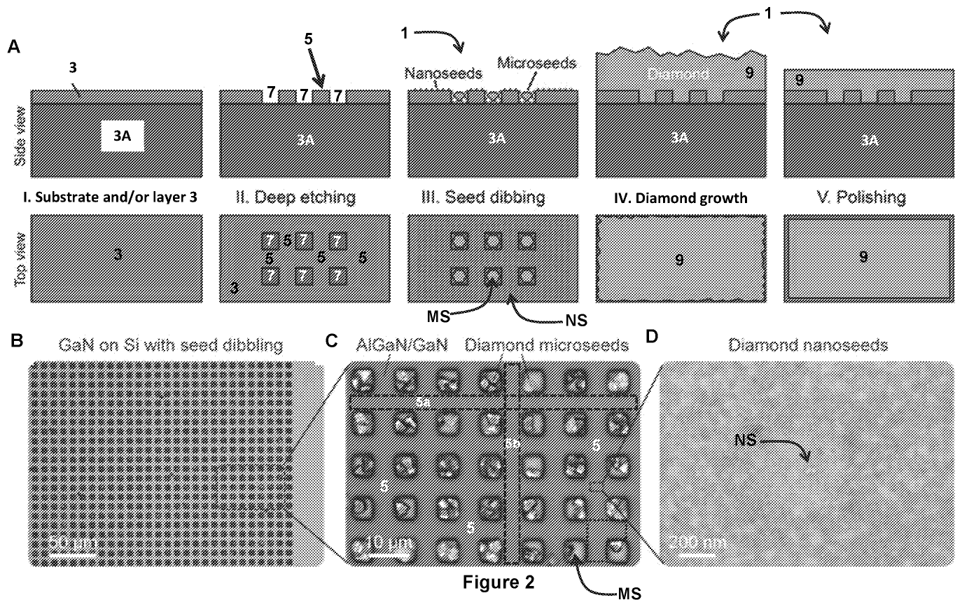

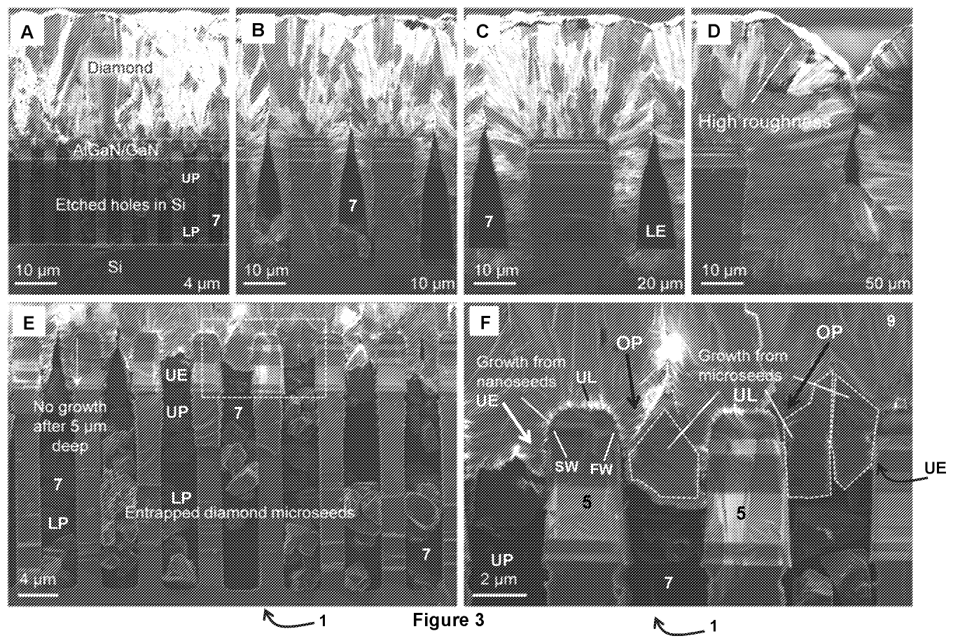

FIGS. 1C, 1D, 2A to 2D, 3A, 3E, 3F, 4A to 4B, and 5A to 5D show exemplary diamond devices or diamond structures 1 according to the present disclosure. FIGS. 1A to 1D and FIG. 2A show an exemplary method for producing a diamond device or diamond structure 1.

The diamond device or structure 1 comprises, for example, at least one supporting layer or material 3 including at least one or a plurality of support structures 5 inside the at least one supporting layer or material 3. The diamond device or structure 1 further includes a plurality of holes, dimples, wells, depressions, trenches, or recesses 7 defined by the at least one or the plurality of support structures 5.

The diamond device or structure 1 may further include at least one or a plurality of diamond micro-seed MS, and a plurality of diamond nano-seeds NS located in each recess 7 or in the plurality of recesses 7.

The device or structure 1 may, for example, comprise or consist of a single supporting layer or material 3 provided/deposited on or superposed on an underlying or holding substrate 3A.

The single supporting layer or material 3 provided on or superposed on an underlying or holding substrate 3A may, for example, be monolithic with or consist of the same material as that of the underlying or holding substrate 3A. FIG. 1C shows an exemplary monolithic structure in which the supporting layer or material 3 and the underlying substrate 3A consists of the same material. The supporting layer or material 3 is, for example, defined by the recesses 7 and the support structure(s) 5 defined in the monolithic material. The remaining material, which is recess-free and the support structure-free, defines the underlying or holding substrate 3A. One or more additional layers or materials may, for example, be provided on the supporting layer or material 3 of FIG. 1C.

The device or structure 1 may, for example, comprise or consist of a plurality of layers or materials 3 provided/deposited on or superposed on an underlying or holding substrate 3A.

The plurality of supporting layers or materials 3 are, for example, superposed layers or materials 3.

The device or structure 1 may, for example, comprise or consist of a single layer or material 3 or a plurality of layers or materials 3 provided/deposited on or superposed on a plurality of underlying or holding layers/materials 3A, or alternatively provided/deposited on or superposed on a single underlying or holding layer/material 3A.

The outer layer or material 3 (or the outer surface thereof) upon which a diamond layer or material 9 is deposited or directly deposition is, for example, a diamond-free layer or diamond-free material.

FIGS. 1A, 1B, 1E and 2 show further exemplary devices or structures 1 comprising or consisting of an underlying or holding substrate or layer 3A.

The supporting layer or material 3 may, for example, comprises or consists of GaN (Gallium Nitride) or AlGaN (Aluminum Gallium Nitride), AlN (Aluminum Nitride) or buffer layers, or super lattices.

The supporting layer or material 3 may, for example, be AlN-free, or the outer surface supporting layer or material 3 upon which the diamond layer or material 9 is to be provided or deposited may, for example, be AlN-free.

The supporting layer or material 3 may, for example, comprises or consists of GaN and AlGaN, with varying contents of Al; or may comprises or consists of GaN and AlGaN with varying contents of Al and include other atoms or materials for example carbon or iron, or may include semiconductor dopants, for example, Si and/or Mg.

The GaN and/or AlGaN layer may, for example, be located on a substrate 3A, as previously mentioned. The substrate 3A may, for example, comprises or consists of Si (silicon), SiC (silicon carbide), Ga₂O₃ (gallium oxide), GaAs (gallium arsenide), sapphire, diamond, borosilicate or quartz.

The substrate 3A and/or the supporting layer or material 3 may, for example, comprises or consists of steel, stainless steel, sapphire, borosilicate, quartz, alumina, or tungsten carbide.

FIGS. 2B to 2D and 3A, 3E, 3F and 4 show an exemplary diamond device 1 according to the present disclosure in which the supporting layer or material 3 comprises GaN and the substrate 3A, upon which the GaN is provided, comprises or consists of Si.

The support structure or structures 5 are located inside the supporting layer or material 3, or inside the plurality of supporting layers or materials 3. The support structure or structures 5 may be formed, for example, via selective removal or etching for example by mechanical machining, chemical etching, physical and/or chemical plasma etching, or laser micro-structuration, of a portion or portions of the supporting layer (s) or material (s) 3 to define the recesses 7.

The support structure or structures 5 may alternatively be formed, for example, by selective growth or deposition of the supporting layer (s) or material (s) on the substrate 3A to define the recesses 7.

The (removed portions) recesses 7 may partially traverse the supporting layer(s) or material(s) 3 with a bottom or floor FL of the recess 7 being defined by the supporting layer or material 3. The recesses 7 may fully traverse the supporting layer(s) or material(s) 3 with a bottom or floor FL of the recess 7 being defined by the underlying or holding substrate or layer 3A. In another exemplary embodiments, the recesses 7 may partially extend into the underlying or holding substrate or layer 3A and a bottom or floor FL of the recess 7 is defined by the underlying or holding substrate or layer 3A. This may, for example, permit further attachment or anchoring of the diamond layer 9 to the underlying or holding substrate or layer 3A.

The support structure or structures 5 comprise or consist of, for example, pillars, props, or protrusions. The support structure or structures 5 extend in an upward direction UD and/or away from the underlying or holding substrate or layer 3A. The support structure or structures 5 extend, for example, in an upward direction UD, and/or away from a plane UDP defined by the underlying or holding substrate or layer 3A, and/or a diamond layer or material 9.

The support structure or structures 5 extends, for example, in a direction UD (substantially) perpendicular to a plane UDP defined by the underlying or holding substrate or layer 3A, or and/or a diamond layer or material 9.

The support structure or structures 5 may, for example, include a plurality of first 5a and second 5b intersecting and protruding elongated ridges (see, for example, the dashed elements 5a, 5b of FIG. 2D) delimiting or defining a grid shape. Such a profile is, however, solely shown as an example and the profile of the support structure 5 is not limited to such a profile.

As previously mentioned, the support structure(s) 5 define or delimit a plurality of recesses 7. The recesses 7 extend partially or fully through the supporting layer or material 3 or the plurality of supporting layers or materials 3 as previously mentioned.

The supporting layer(s) or material(s) 3 comprises, for example, a regularly repeating and/or a periodic plurality of recesses 7.

The plurality of recesses 7 may define or comprise, for example, a repeating symmetric pattern of recesses 7. A recess 7 is, for example, periodically repeated. The distance between each recess 7 may have a value P or the recesses may or may not repeat periodically. When repeated periodically, repetition may occur with the same period value P.

Recesses 7 are for example, separated by a distance SP (see FIG. 1D for example), that may for example have a value between (i) WD/2 and (ii) 10×WD (ten times WD) or 20×WD or 30×WD, for the exemplary embodiment of FIG. 2C, between 2 μm and 40 μm, for example 8m.

The recesses 7 can be, for example, configured or laid-out as a periodically repeating recess array or arranged in a periodic array arrangement. The periodic arrangement may define a symmetric geometry or pattern. The plurality of recesses 7 can thus be configured as a periodic recess array or arranged in a periodic array arrangement across the supporting layer or material 3 or on some portions of the supporting layer or material 3.

The recess arrangement may also be non-periodic, partially periodic or have varying period. The arrangement may, for example, define an asymmetric geometry or pattern. Recesses 7 in these arrangements may also, for example, be separated by the distance SP.

The recess or each recess 7 may have a symmetric cross-sectional form or geometry (for example, in the direction UDP), for example, substantially rectangular or square as shown in the Figures. The recesses 7 may, however, additionally or alternatively have other cross-sectional shapes such as circular, triangular, trapezoidal or elliptical profiles.

The recess or each recess 7 may additionally or alternatively have asymmetric cross-sectional shapes.

The recess or each recess 7 may have a symmetric top-view form or geometry, for example, substantially rectangular or square as shown in the Figures. The recesses 7 may, however, additionally or alternatively have other cross-sectional shapes such as circular, triangular, trapezoidal, polygonal or elliptical profiles.

The recess or each recess 7 may additionally or alternatively have asymmetric top-view shapes.

The recess or recesses 7 may have an opening width WD, for example, in the (in-plane) planar direction UDP of the supporting layer or material 3, having for example a value between 1 μm and 2000 μm, or between 1 μm and 1000 μm, or between 1 μm and 500 μm, or between 1 μm and 400 μm, or between 1 μm and 250 μm, or between 1 μm and 100 μm, or between 1 μm and 50 μm, or between 2 μm and 200 μm, or between 2 μm and 50 μm, or between 2 μm and 20 μm, or between 4 μm and 15 μm, or between 3 μm and 6 μm. The opening width WD may have, for example, a value between 4 μm and 10 μm, or for example a value of 4 μm or 8 μm.

The recesses 7 may, for example, have non-identical or different opening widths WD. The recesses 7 may, for example, include a plurality of recesses 7 having a first opening width WD1 and a plurality of recesses 7 having a second opening width WD2, the first and second opening widths being of different values. A plurality of recesses 7 having, for example, third and fourth opening widths etc. may also be included. The value of the first and second opening widths WD1, WD2 is, for example, a value as previously set out in above for the opening width WD.

The recess or recesses 7 may have a depth DP, for example, extending in the direction UD perpendicular to a (in-plane) planar direction UDP of the supporting layer or material 3 or a direction of extension of the support structures 5, having for example a value between 1 μm or 2 μm and 1000 μm, for example a value of 500 μm; or between 2 μm and 300 or 400 μm, or between 2 μm and 100 μm, or between 2 μm and 10 or 20 μm, for example 5 μm or 9 μm, or between 2 μm and 5 μm.

The recesses 7 may, for example, have non-identical or different depths DP. The recesses 7 may, for example, include a plurality of recesses 7 having a first depth DP1 and a plurality of recesses 7 having a second depth DP2, the first and second opening depths being of different values. A plurality of recesses 7 having, for example, third and fourth depths etc. may also be included. The value of the first and second opening depths DP1, DP2 is, for example, a value as previously set out in above for the depth DP.

As previously mentioned, the in-plane or planar direction UDP can, for example, be defined by the plane of extension of the underlying or holding substrate or layer 3A, and/or of a diamond layer or material 9, and/or of the supporting layer or material 3. As previously mentioned, the direction UD is, for example, a direction extending in an upward direction UD and/or away from the underlying or holding substrate or layer 3A. The direction UD is, for example, (substantially) perpendicular to a plane defined by the underlying or holding substrate or layer 3A, and/or by a diamond layer or material 9, and/or by the supporting layer or material 3.

The recesses 7 are, for example, located on at least one area or a plurality of separated or distributed areas of the at least one supporting layer or material 3, or the recesses 7 are located fully across the at least one supporting layer or material 3.

The recesses 7 are, for example, located on at least 1% or 5% or 10% or 20% or 30% of the surface area of the at least one supporting layer or material 3. The recesses 7 are, for example, located on between 1% and 90% or between 5% and 70% or between 5% and 50% or between 10% and 40% or between 20% and 40% or between 30% and 40% of the surface area of the at least one supporting layer or material 3.

As mentioned, at least one or a plurality of diamond micro-seed MS, and a plurality of diamond nano-seeds NS are, for example, located in each recess 7 or in the plurality of recesses 7.

The recesses 7 (or each recess 7) includes at least one wall W extending to fully surround or fully encircle one or more diamond micro-seed MS. The one or more diamond micro-seed MS is located fully or partially inside the enclosure or space defined by the at least one wall W.

The support structure (or structures) 5 includes or defines the at least one wall W.

The support structure 5 defines an opening OP and an upper enclosure UE of the recess 7 (or recesses 7). A rim or outer rim RM, for example, of the support structure or structures 5 defines the opening OP.

The upper enclosure UE of the recess 7 may, for example, extend fully along the depth DP of the recess 7 and to the floor FL of the recess 7 (see for example FIG. 1B).

Alternatively, or additionally, the upper enclosure UE of the recess 7 may, for example, extend partially along the depth DP of the recess 7 and not to the floor FL of the recess 7 (see for example FIGS. 2E, 2F).

The support structure (or structures) 5 may, for example, include an upper portion UP and a lower portion LP. For example, the upper portion UP defines an upper-half, and the lower portion LP defines a lower-half of the support structure 5 (see for example FIG. 3E).

The upper portion UP of support structure 5 defines the opening OP and the upper enclosure UE of the recess 7 (or recesses 7), where the upper enclosure UE partially extends into or along the depth DP of the recess 7. The lower portion LP of support structure 5 defines, for example, a lower enclosure LE of the recess 7 (or recesses 7). The upper enclosure UE is, for example, located in the upper quarter of the recess 7 with respect to the opening OP, or alternatively the upper 15% or 10% of the recess 7. The lower enclosure LE is, for example, located in the lower half or lower quarter of the recess 7 with respect to the opening OP.

At least one diamond micro-seed MS is located, for example, inside the opening OP and/or the upper enclosure UE. The upper enclosure UE includes the opening OP.

The micro-seed or micro-seeds MS may, for example, substantially occupy or fill the opening OP or width WD of the upper enclosure UE of the recess 7. The micro-seed or micro-seeds MS may, for example, substantially occupy or fill the depth DP of the upper enclosure UE, or the depth DP of the recess 7. This permits satisfactory anchoring of the diamond layer 9 of the device 1. It is to be noted that the size and dimensions of the recesses 7 of the exemplary embodiments detailed further below, demonstrating the innovative concept of the present disclosure, are provided as examples and the present disclosure is not limited to such dimensions or sizes.

The diamond micro-seed MS has, for example, a size/extension DD or a diameter DD that is between 40% and 95%, or between 60% and 95% or between 75% and 90% or between 75% and 95% of a size or diameter of the opening OP of the recess 7.

The size/extension or diameter of the diamond micro-seed MS and/or the opening OP can be measured, for example, in the plane of the supporting layer or material 3 (or substrate 3A), or in the (in-plane) planar direction UDP (see for example, FIG. 1B).

The size/extension or the diameter is measured between outer extremities of the micro-seed MS. The size/extension DD or the diameter DD can be defined, for example, as being the largest or longest size/extension DD or the largest or longest diameter DD measured or determined in a direction extending inside the plane defined by the supporting material(s) or layer(s) 3 holding or enclosing the diamond micro-seed MS.

In other words, the value of the size/extension DD or the diameter DD of the diamond micro-seed MS is between 0.6 times the size or diameter of the opening OP and 0.95 times the size or diameter of the opening OP; or is between 0.75 times the size or diameter of the opening OP and 0.95 times the size or diameter of the opening OP.

As mentioned, the size or diameter of the opening OP can be measured, for example, in the (in-plane) planar direction UDP. The size or diameter of the opening OP can be measured, for example, using scanning electron microscopy/microscope SEM, Atomic force microscopy (AFM) or optical microscopy. The size/extension DD or diameter DD of the diamond micro-seed MS can be measured, for example, using SEM, Atomic force microscopy (AFM) or optical microscopy.

The diamond micro-seed MS, for example, may have or delimit a cross-sectional area AA that is between 30% and 95% or between 60% and 95% or between 75% and 95% of a cross-sectional area defined by the opening OP of the recess 7. These cross-sectional areas can be measured, for example, in a similar manner to that of the size or diameter of the opening OP, for example in the (in-plane) planar direction UDP, using, for example, SEM or an optical microscope.

The depth DP of the upper enclosure UE and/or the recess 7 may, for example, be between 60% and 1000%, or between 60% and 500%, or between 80% and 150%, or between (i) 60%, 80% or 100% and (ii) 120% of a size/extension or a diameter of the at least one diamond micro-seed MS. The size/extension or the diameter of the diamond micro-seed MS is, for example, measured in the direction UD that is, for example, a direction extending in the direction of extension of the support structure or structures 5, and/or a direction away from the underlying or holding substrate or layer 3A, and/or a diamond layer or material 9, and/or the underlying supporting layer or material 3. The direction UD is, for example, (substantially) perpendicular to a plane defined by the underlying or holding substrate or layer 3A, and/or by a diamond layer or material 9, and/or by the supporting layer or material 3. The size/extension or the diameter is measured, for example, between outer extremities of the micro-seed MS. The size/extension DD or the diameter DD can be defined, for example, as being the largest or longest size/extension DD or the largest or longest diameter DD measured or determined in this direction.

Only one, only two, or only three diamond micro-seeds MS are, for example, located or held inside the opening OP and/or the upper enclosure UE. Only one, only two, or only three diamond micro-seeds MS occupy or fill, for example, the cross-sectional area defined by the opening OP of the recess 7. Only one, only two, or only three diamond micro-seeds MS occupy or fill, for example, the depth DP of the upper enclosure UE and/or the recess 7.

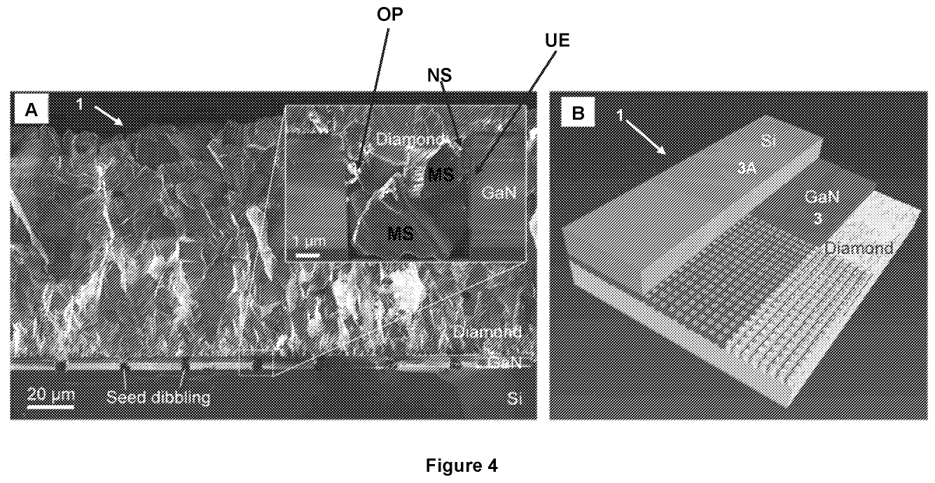

FIG. 4A shows, for example, one diamond micro-seeds MS located or held inside the opening OP and/or the upper enclosure UE. A plurality of nano-seeds may, for example, be simultaneously located or held inside the opening OP and/or the upper enclosure UE with the micro-seed MS.

The diamond micro-seed(s) MS may for example comprise or consist of particles or primary particles and/or deagglomerated or aggregated particles of micro-diamonds produced, for example, by fracturing or cleavage of a natural or synthetic diamond particle, or be synthesized in a diamond reactor. The diamond micro-seeds MS may comprise or consist of irregular or regular-shaped monocrystalline or polycrystalline diamond particles or chips or plates.

The diamond micro-seed MS size or dimensions can be determined using, as previously mentioned, SEM or confocal microscope. Particle size distribution can be measured or determined by dynamic light scattering (DLS), acoustic spectrometry or differential sedimentation.

The diamond micro-seed MS may comprise or consist of, for example, a particle or crystal having a diameter or size/extension between 1 μm and 2000 μm, or between 1 μm and 500 μm, or between 1 μm and 250 μm, or between 1 μm and 100 μm, or between 1 μm and 50 μm. The particle or crystal may have, for example, a diameter or size/extension between 2 μm and 20 μm, or between 3 μm and 7 μm, or a diameter or size/extension of, for example, 3 μm or 4 μm. The size/extension or diameter of the diamond micro-seed MS can be measured, for example, using SEM or confocal microscope as mentioned above. The size/extension or the diameter is measured, for example, between outer extremities of the micro-seed MS. The diamond micro-seed MS may have a diameter or size/extension within or of the above values when measured in either or both of the directions previously mentioned in relation to diameter or size/extension measurements or determination, for example, in the directions UD and/or UDP.

As previously mentioned, a plurality of diamond nano-seeds NS can be located in each recess 7 or in the plurality of recesses 7. The upper portion UP and/or upper enclosure UE include, for example, a plurality of distributed diamond nano-seeds NS.

The diamond nano-seed(s) NS comprise or consist of, for example, particles, or primary particles and/or deagglomerated or aggregated particles of nano-diamonds produced, for example, by standard diamond detonation process using oxygen-deficient explosive mixture of TNT/RDX detonated in a closed chamber, or be synthesized in a diamond reactor.

The diamond nano-seeds NS may, for example, comprise or consist of diamond crystals, for example, (substantially) spherical diamond crystals.

The diamond nano-seed NS size/extension or diameter can be determined using SEM, high resolution transmission electron microscopy HRTEM, transmission electron microscopy TEM, Atom Probe Tomography, SAXS (Small Angle X-Ray Scattering) and Ultra-SAXS and particle size distribution measured by dynamic light scattering (DLS).

The diamond nano-seed NS comprises or consists of a particle having a diameter or size/extension for example <1000 nm, for example between 1 nm (or 2, 3, 4, or 5 nm) and a value less than 1000 nm, or between 1 nm (or 2, 3, 4, or 5 nm) and 900 nm, or between 1 nm (or 2, 3, 4, or 5 nm) and 500 nm, or between 1 nm (or 2, 3, 4, or 5 nm) and 300 nm, or between 1 nm (or 2, 3, 4, or 5 nm) and 200 nm, or between 1 nm (or 2, 3, 4, or 5 nm) and 100 nm, or between 1 nm (or 2, 3, 4, or 5 nm) and 50 nm, or between, for example, 1 nm or 3 nm and 15 nm, or between, for example, 4 nm and 1 nm. The diamond nano-seed NS comprises or consists of, for example, a particle having a diameter or size/extension of 5 nm. The size/extension or diameter of the diamond nano-seed NS can be measured, for example, using SEM or TEM or HRTEM, as previously mentioned. The size/extension or the diameter is measured, for example, between outer extremities of the nano-seed NS. The size/extension or the diameter can be defined, for example, as being the shortest or longest size/extension or the shortest or longest diameter measured or determined on the nano-seed NS.

The diamond micro-seed MS particle size may, for example, between (i) 10, or 50, or 100, or 1000 and (ii) 2000 times larger than that of the diamond nano-seed NS particle size.

The diamond micro-seeds MS and/or the diamond nano-seeds NS comprise or consist of monocrystalline or polycrystalline diamond; or monocrystalline or polycrystalline diamond which can be either intrinsic or doped, with or without defects or color-centers.

The micro-seed or micro-seeds MS define, for example, a nucleation or coalescence site for diamond crystal growth. The nano-seeds NS define, for example, nucleation sites for conformal diamond growth.

As mentioned, each recess 7 or the recesses 7 are defined by at least one wall W and at least one floor FL. The plurality of diamond nano-seeds NS are, for example, located or held on the at least one wall W and/or on the at least one floor FL.

The at least one wall W fully surrounds the micro-seed or micro-seeds MS. The at least one wall W extends in a similar manner to the support structure 5, that is, in an upward direction UD and/or away from the underlying or holding substrate or layer 3A. The at least one wall W extends, for example, in a direction UD, and/or away from a plane UDP defined by the underlying or holding substrate or layer 3A, and/or a diamond layer or material 9.

The micro-seed or micro-seeds MS are located fully or partially inside the at least one wall W, or inside the enclosure or space defined by the at least one wall W. A plurality of diamond micro-seeds MS is, for example, located inside each recess 7 or inside the recesses 7. The diamond micro-seeds MS are, for example, stacked to fill each recess 7 or fill the plurality of recesses 7, as can be seen for example in FIGS. 3A, 3E and 3F.

For example, in the case where the upper enclosure UE of the recess 7 extends partially along the depth DP of the recess 7 and not to the floor FL of the recess 7 (see for example FIGS. 2E, 2F), the micro-seeds MS may be stacked inside the recess 7.

The micro-seeds MS are, for example, stacked to extend to the upper enclosure UE of the recess 7. The micro-seeds MS are stacked, for example, to extend to a position located within at least 60%, or 40% or 20% or 15% or 10% or 5% of the opening OP of the recess 7 or the outer rim RM of the opening OP, or to a position located within or surrounded by the opening OP or the outer rim RM.

The diamond micro-seeds MS are, for example, stacked from a floor FL of the recess 7, as for example, shown in FIGS. 3A and 3E.

The support structure 5 and the upper portion UP includes, for example, a first wall FW, a second wall SW and an upper landing UL extending between the first and second walls FW, SW. A plurality of diamond nano-seeds NS can be located or distributed, for example, on the upper landing UL and on the first and second walls FW, SW.

The upper portion UP may, for example, comprise a plurality of walls W and a plurality of upper landings UL extending between the walls W, and a plurality of diamond nano-seeds NS are located or distributed on the upper landings UL and on the walls W.

The diamond nano-seeds NS are distributed on or attached to a surface 11 of the supporting layer or material 3, as shown for example, in FIGS. 1D and 1E. The diamond nano-seeds NS are distributed on or attached to a surface 11 at a density, for example, between 1×10⁸ cm⁻² and 1×10¹³ cm⁻², or between 1×10⁹ cm⁻² and 1×10¹² cm⁻², or between 1×10¹⁰ cm⁻² and 1×10¹² cm⁻², or between 10⁸ cm⁻² and 10¹⁴ cm⁻², or between 10⁸ cm⁻² and 10¹³ cm⁻², or between 10¹ cm⁻² and 10¹³ cm⁻², or between 10¹ cm⁻² and 10¹² cm⁻². The surface 11 includes, for example, the planar surface and the surface defined by the walls and floors of the recesses 7.

The diamond device or structure 1 may further include a diamond layer 9 attached to the at least one supporting layer or material 3. The diamond layer 9 is for example attached directly to the supporting layer or material 3.

The diamond layer 9 is, for example, a high purity diamond layer comprising at least 95% carbon atoms. The diamond layer 9 has, for example a thickness >6 μm.

The diamond layer 9 may, for example, be a doped diamond layer 9, for example, doped p-type. The supporting layer(s) or material(s) 3 may, for example be doped n-type. The diamond layer 9 may, for example, may have different regions with different doping types and different concentration of the dopant atoms. The diamond layer 9, for example, may have color-centers such as NV-centers.

The diamond layer 9 may for example be a polished diamond layer 9. The polished diamond layer 9 may be directly attached to the supporting layer or material 3. The polished diamond layer 9 may have, for example, a sub-nanometer surface roughness.

The diamond device or structure 1 may, for example, be interlayer-free between the diamond layer 9 and the at least one supporting layer or material 3. The diamond device or structure 1 may, for example, be AlN interlayer-free, SiN interlayer-free or SiC interlayer-free between the diamond layer 9 and the at least one supporting layer or material 3.

The diamond layer 9 extends, for example, from the micro-seeds MS located in the openings OP and/or in the upper enclosures UE and extends away from the supporting layer or material 3. The diamond layer 9 extends, for example, only from the diamond micro-seeds MS in the openings OP and/or in the upper enclosures UE, and/or from the plurality of nano-seeds NS distributed on the supporting layer or material 3.

The diamond micro-seeds MS are arranged inside the recesses 7 and the diamond nano-seeds NS are distributed on the supporting layer or material 3 and inside the recesses 7 to chemically bond and/or mechanically anchor or fix the diamond layer 9 to the supporting layer or material 3.

The diamond micro-seed MS and the diamond nano-seeds NS may both define diamond crystal growth nucleation or coalescence sites on the at least one supporting layer or material 3.

The device or structure 1 include a diamond pillar embedded inside each recess 7 or the plurality of recesses 7, as can be seen for example in FIGS. 4A and 4B. The pillar extends, for example, from the floor FL of the recess 7. This assures strong anchoring of the diamond layer 9 and improved shear strength at the diamond 9/layer 3 interface.

The lower enclosure LE of each recess 7 or the plurality of recesses 7 may, for example, be diamond growth-free.

The diamond device or structure 1 may be included, for example, in an electronic device or integrated circuit, or may be further processed to form an electronic device or integrated circuit.

The present disclosure also concerns a method for producing the diamond device or structure 1. FIG. 2A shows a schematic diagram showing different possible steps of an exemplary diamond device or structure fabrication method according to the present disclosure.

The method comprises, for example, providing the above described at least one supporting layer or material 3 including the at least one or a plurality of support structures 5 inside the at least one supporting layer or material 3 and the plurality of recesses 7 defined by the support structures 5. The method further comprises carrying out diamond seeding to provide at least one diamond micro-seed MS and a plurality of diamond nano-seeds NS in each recess 7 or in the plurality of recesses 7.

The provision of such a supporting layer(s) or material(s) 3 may include, for example, providing at least one supporting layer or material 3, or a plurality of superposed supporting layer or material 3; and etching or removing the supporting layer(s) or material(s) 3 to produce the plurality of recesses 7 inside.

As previously mentioned, there may be, for example, a single supporting layer or material 3 provided/deposited on or superposed on the underlying or holding substrate 3A, or a plurality supporting layer or material 3 provided/deposited on or superposed on the underlying or holding substrate 3A. Etching may be carried to etch partially of fully through the single supporting layer or material 3, partially of fully through the plurality of supporting layers or materials 3, or fully through the supporting layer(s) or material(s) 3, and partially through the underlying or holding substrate 3A.

When the device or structure 1 includes a plurality of supporting layers or materials 3, etching of the plurality of supporting layers or materials 3 is thus carried out to produce a plurality of recesses 7 inside the plurality of supporting layers or materials 3. When the device or structure 1 includes a substrate 3A and at least one or a plurality of layers attached to the substrate 3A, etching of the at least one or the plurality of layers attached to the substrate 3A is carried out to produce a plurality of recesses 7 only inside the at least one or the plurality of layers, or inside the at least one or the plurality of layers and the substrate 3A.

Etching is carried out to provide recesses 7 and support structures 5 as previously described.

Etching or removal may be carried out, for example, using reactive ion etching RIE, plasma etching Ion milling, chemical etching, mechanical etching, laser etching or mechanical machining. A mask layer is, for example, provided on the supporting layer or material 3 to form etching at the desired locations and provide a desired recesses arrangement or pattern.

The mask layer may then be subsequently removed following etching of the material or materials to a desired depth.

The mask layer is, for example, a hard mask layer to permit a sufficient material etching depth. At least one material, for example, SiO₂, HSQ (Hydrogen Silses Quioxane), photoresist, or metals for example Pt may be used as a hard mask layer.

Diamond seeding may include, for example, providing micro-seeds MS on the outer surface 11 of the supporting layer or material 3 and agitating the supporting layer or material 3 to displace micro-seeds MS into each recess 7 or into the recesses 7; and providing nano-seeds NS on the outer surface 11 of the supporting layer or material 3 and agitating the supporting layer or material 3 to distribute the nano-seeds NS into each recess 7 or recesses 7 and across the surface 11 of the supporting layer or material 3.

Agitation may, for example, be carried out by ultrasonic agitation.

Diamond seeding may include providing the micro-seeds and/or nano-seeds via, for example, immersion, drop casting, spraying, electrostatic spray or spin-coating of a suspension or suspensions containing the diamond seeds.

Diamond seeding may include providing the micro-seeds via, for example, placing diamond seeds, for example, diamond plates or chips or (large) particles into each recess 7 or into the recesses 7, for example, manually or using pick-and-place machines.

The micro-seed MS particle size to be provided on the outer surface 11 of the supporting layer or material 3 can, for example, be chosen based on D50 median size, or micro-seed MS particle size determined based on any one of the measurement means mentioned above. The micro-seed MS particle size is chosen based on the size of the opening OP of the recess 7 and, for example, chosen to be relatively close to the size of the opening OP of the recess 7 so as to substantially fill the recess 7, as explained previously. Such filling can thus be obtained adapting the size of the opening OP of the recess 7 to the particle size (or average particle size), or vice versa.

The nano-seed NS particle size to be provided on the outer surface 11 of the supporting layer or material 3 can, for example, be chosen based on particle size distribution measured using dynamic light scattering (DLS), or nano-seed NS particle size determined based on any one of the measurement means mentioned above.

The micro-seeds MS and the nano-seeds NS may, for example, be provided together or simultaneously on the surface 11 of the supporting layer or material 3 for agitation. Rinsing and/or drying of the supporting layer or material 3 (or device 1) is then carried out.

Alternatively, the micro-seeds MS may, for example, first be provided on the surface 11 of the supporting layer or material 3 and agitated to distribute the micro-seeds MS. The nano-seeds NS may, for example, then be provided on the surface 11 of the supporting layer or material 3 and agitated to distribute the nano-seeds NS. Rinsing and/or drying of the supporting layer or material 3 (or device 1) may, for example, be carried out between micro-seed MS and nano-seed NS distribution and after nano-seed NS distribution, or only after nano-seed NS distribution. Alternatively, the nano-seed NS distribution may be carried out prior to micro-seed MS distribution.

The micro-seeds MS and/or nano-seeds NS may, for example be provided only once, or multiple times sequentially or without a certain order to obtain the desired densities.

It is noted that it is not necessary that all recesses 7 contain micro-seeds MS and nano-seeds NS, a plurality of recesses 7 containing micro-seeds MS and nano-seeds NS allows the results described herein to be obtained.

A seed dibbling method of the present disclosure is thus assured by the provision of the recesses 7, for example, in the supporting layer(s) or material(s) 3; and diamond seeding in the recesses 7 and across the outer surface 11 of the supporting layer or material 3. This is carried out prior to the provision or deposition of a diamond layer 9 on the device 1.

The method of the present disclosure also, for example, includes a diamond growth step of depositing a diamond layer 9 on the diamond seeded supporting layer or material 3. The diamond growth step may be carried out, for example, using chemical vapor deposition CVD, for example, by microwave plasma chemical vapor deposition MPCVD, or low temperature plasma CVD, atmospheric plasma CVD, plasma torch and hot filament CVD.

The diamond layer 9 comprises or consists of, for example, polycrystalline and/or single crystal diamond.

The method further includes, for example, a diamond polishing step of polishing the deposited diamond layer 9. Polishing of the diamond layer 9 may be carried out, for example, using chemical and/or mechanical polishing.

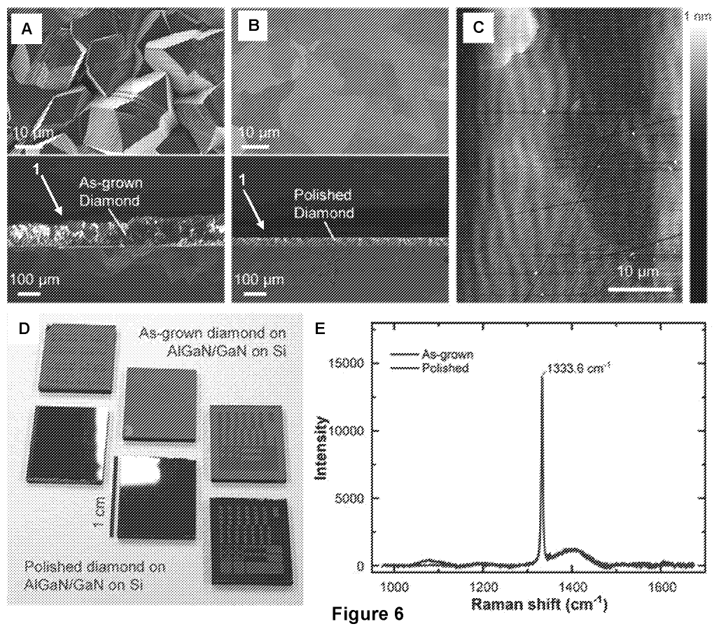

A diamond grinding wheel with large grits can for example be used for an initial fast material removal and planarization of the diamond layer 9. Further fine polishing can then be carried out using, for example, a lapping machine designed for diamond polishing to obtain, for example, a flat mirror finish, as shown for example in FIG. 6D.

A polished diamond layer 9 having a sub-nanometer surface roughness is for example provided using such polishing.

After the polishing, the diamond layer 9 (or device 1) can be cleaned, for example, using acetone and IPA. This can, for example, be followed by a further cleaning step to remove graphitic phases, undesired layers, and other impurities.

As previously mentioned, in the method according to the present disclosure, the supporting layer or material 3 may, for example, comprises or consists of GaN or AlGaN.

The supporting layer or material 3 may, for example, comprises or consists of GaN and AlGaN, the content of Al increasing as the layer or material thickness increases.

The GaN and/or AlGaN layer may, for example, be located on a substrate 3A, as previously mentioned. The substrate 3A may, for example, comprises or consists of Si (silicon), SiC (silicon carbide), GaAs, Ga₂O₃, borosilicate, quartz, or sapphire. The recesses 7 may, for example, extend to or extend into the substrate.

To demonstrate the anchoring and strong attachment of diamond and the advantages of the method and device 1 of the present disclosure, the Inventors provide herein experimental results for an exemplary embodiment of diamond grown on GaN and/or AlGaN, and in particular to diamond grown on AlGaN/GaN-on-Si substrates. However, it should be understood that the present disclosure is not limited to this specific embodiment.

AlGaN/GaN-on-Si substrates were used for seed dibbling and diamond growth, enabling, for example, the integration of diamond on GaN-on-Si HEMTs for thermal management and power electronics applications.

A Si substrate 3A including a GaN and/or AlGaN layer 3 deposited thereon was used. The GaN and/or AlGaN layer 3 has an exemplary thickness of approximately 3 μm or 5 μm. A relatively thin buffer layer may be present directly on the Si and between the outer GaN or AlGaN layer 3. The seed dibbling started with the deep etching of holes 7 in the supporting layer/substrate before the growth (step II in FIG. 2(a)). The GaN 3 etching step was performed using inductive-coupled plasma (ICP) etching using Cl₂/BCl₃/Ar. Afterwards, a standard Bosch Si-etching process was used for further etching of the substrate 3A to adjust the aspect ratio of the holes 7. Here, the Si etching step was done to form high aspect ratio holes 7 only to study the effect of hole depth DP, however in the rest of the study an optimized depth DP was used that did not require the Si etching step or relatively deep etching. A SiO₂ was used as hard mask for all etching steps, deposited using plasma enhanced CVD (PECVD) at 300° C.

Then, the substrates 3, 3A were seeded with micro- and nano-seeds MS, NS (step III in FIG. 2(a)). First, the nano-seeding was done using a 0.5% wt. suspension of diamond nanoparticles NS of 5-10 nm in methanol with ultrasonic agitation for 10 min followed by an IPA rinsing and drying using nitrogen. Then, the micro-seeding MS was performed by immersion of the substrate in a 10% wt. suspension of undoped diamond particles of 3-4 μm in isopropanol (IPA), and agitated by ultrasonication for 10 minutes. The seed dibbling method resulted in the incorporation of diamond microseeds MS on the patterned GaN-on-Si substrate 3, 3A (FIG. 2(b)), which can efficiently entrap the large microseeds MS inside the holes 7 (FIG. 2(c)). The diamond nanoseeds NS had also covered the substrate 3, 3A with a high density (>10¹¹ cm⁻¹), as shown in FIG. 2(d).

The polycrystalline diamond films 9 were grown on the seeded substrates 3,3A by the microwave plasma chemical vapor deposition (MPCVD) method. The substrate temperatures were fixed at 850° C., with average plasma power of 4 kW and pressure of 130 mbar. The diamond growth rate was kept above 1 μm/h using high purity gasses (9N) with a standard gas ratio (95% H₂, 5% CH₄), and addition of a small amount of nitrogen and/or argon (few ppm).

The as-grown diamond films 9 usually have a relatively high surface roughness (step IV in FIG. 2(a)) and chemical/mechanical polishing steps allow to obtain smooth surfaces (step V in FIG. 2(a)). The diamond polishing may be performed, for example, in a manner that the substrates 3, 3A comprising diamond 9 be mounted on a work head to hold against a horizontal diamond grinding wheel with large grits for an initial fast material removal and planarization of diamond. Then the substrates 3, 3A were polished using a lapping machine specifically designed for diamond polishing to obtain flat mirror finish. After the polishing, the substrates can be cleaned using acetone and IPA followed by a cleaning step using hot H₂SO₄/H₂O₂ mixture to remove the graphitic phases and all other impurities.

Although nanoseeds NS provide excellent surface coverage and high seeding densities, the low thermal conductivity of the nanocrystalline diamond near the interface can result in high TBRs³¹. On the other hand, microseeds MS can result in larger grains and high thermal conductivity, however the presence of voids between the grains near the interface can expose the GaN to the hydrogen plasma in the CVD reactor and result in the etching of GaN^{32,33}. The use of the mixed seeds in the seed dibbling method of the present disclosure offers the benefits of both methods, resulting in larger grains, thus with higher thermal conductivity, along with lower TBR and no damages to the GaN surface³¹.

To optimize and investigate the size and aspect ratio of the holes 7 in the seed dibbling method, seeding steps were performed on fabricated holes 7 with opening size varying from 4 to 50 μm and high depth (˜30 μm), followed by the growth of an approximately 30 μm-thick diamond layer 9. FIGS. 3(a)-(d) show the cross-sectional SEM images of the sizes of 4, 10, 20 and 50 μm, respectively.

Although all the holes 7 were subject to the same seeding process, the entrapment of the microseeds MS was highly dependent on the hole size. The 4 μm holes 7 were the most efficient in capturing the microseeds MS (FIG. 3(a)). However, the 10 μm holes 7 captured fewer microseeds MS (FIG. 3 (b)), and there was almost no microseeds MS captured in the larger holes 7 (FIGS. 3(c) and (d)).

FIG. 3(e) shows that only the seeds at the top 5 μm of the initial substrate contributed to the diamond nucleation and growth. No diamond growth was observed from more than the 5 μm depth, which can be due to the low diffusion of carbon atoms inside holes during the growth and a fast coalescence at the top that can block the nucleation from the deeper seeds. A closer look near the diamond/GaN interface (FIG. 3(f)) reveals that the nanoseeds NS acted as the nucleation points for a conformal growth of diamond layer 9 with a good adhesion to the substrate 3, 3A, while microseeds MS formed nucleation points for larger diamond crystals that contributed to the higher average grain size and higher quality of the polycrystalline diamond film 9. The growth of diamond 9 on all other hole dimensions was mainly due to the presence of nanoseeds NS, and there were almost no microseeds MS to contribute to the growth of larger grains.

The size of the holes 7 did not have any effect on the thickness of diamond 9; however, it highly affected the roughness of the final diamond film 9. The unsuccessful coalescence of the diamond over the 50 μm holes resulted in the formation of dimples on top of the holes 7 with more than 10 μm depth (FIG. 3(d)). The coalescence was significantly improved on the smaller holes 7, resulting in much smaller dimples as well. On the samples with 10 μm and 20 μm holes 7, the coalescence resulted in embedded cavities inside the holes 7 (FIGS. 3(b) and (c)), and the interfaces of the coalescence fronts can also be seen along the entire thickness of the diamond films 9. However, on the 4 μm holes 7 barely any coalescence interface can be seen, only the diamond grains are visible, indicating a much-improved coalescence.

Therefore, an exemplary optimized size of the holes 7 to have both microseeds MS and nanoseeds NS incorporated and contributing to the growth was found to be, for example, a width WD of 4 μm and depth DP of 5 μm, which (substantially) match the average size (for example, D50 median size) of microseeds MS used in this study (3-4 μm). Such a depth avoids deeper etch and simplifies the fabrication method. However, deeper depths are also possible in the case where a microseed(s) MS are positioned in the upper level (upper enclosure) of the recess 7, for example, within the depth DP of 5 μm from the opening OP of the hole 7.

Based on these results, AlGaN/GaN-on-Si substrates were structured with these dimensions for the following experiments. The seed dibbling method enabled the reliable and reproducible growth of thick diamond layers on AlGaN/GaN-on-Si, even thicker than 100 μm (20 h of growth), with no signs of film delamination or cracks (FIG. 4(a)). The diamond grown from the nanoseeds NS filled up the spaces between the microseeds MS and the side walls (inset of FIG. 4(a)), thus significantly improved their adhesion to the substrate 3, 3A.

X-ray tomography (XRT) images of the substrate show a complete growth and coalescence of diamond inside and over the dibbled regions, resulting in a uniform diamond layer 9 with the contribution of all the seeds MS, NS to the growth without any voids or cavities (FIG. 4(b)). Moreover, diamond pillars were formed embedded in the substrate that significantly improved the adhesion to the substrate and the shear strength at the interface.

The presence of holes 7 in the substrate 3, 3A in the seed dibbling method had a strong impact on the adhesion and the residual stress in the grown diamond film 9. The Inventors observed that in substrates 3, 3A without the seed dibbling, even with the use of SiN or AlN interlayers, the diamond film 9 either delaminated during the cool down in the CVD reactor or developed large cracks during later fabrication processes. However, micro-structuring the substrate 3, 3A together with the seed dibbling method, even on small a portion of the substrate 3, 3A, significantly enhanced the adhesion of the diamond film, and no more delamination or cracks were observed.

To evaluate the effect of the seeding types used in the seed dibbling method on the quality of the diamond film 9, different substrates 3, 3A were seeded using nanoseeds NS, microseeds MS and a mixture of both, followed by a 10 h diamond growth (16 μm thick). Micro-Raman spectroscopy was used to measure the stress, phase purity and the crystalline quality of the diamond 9, and the profile of Raman shift along the diamond thickness was obtained by changing the focus of the incident beam within the film³⁴.

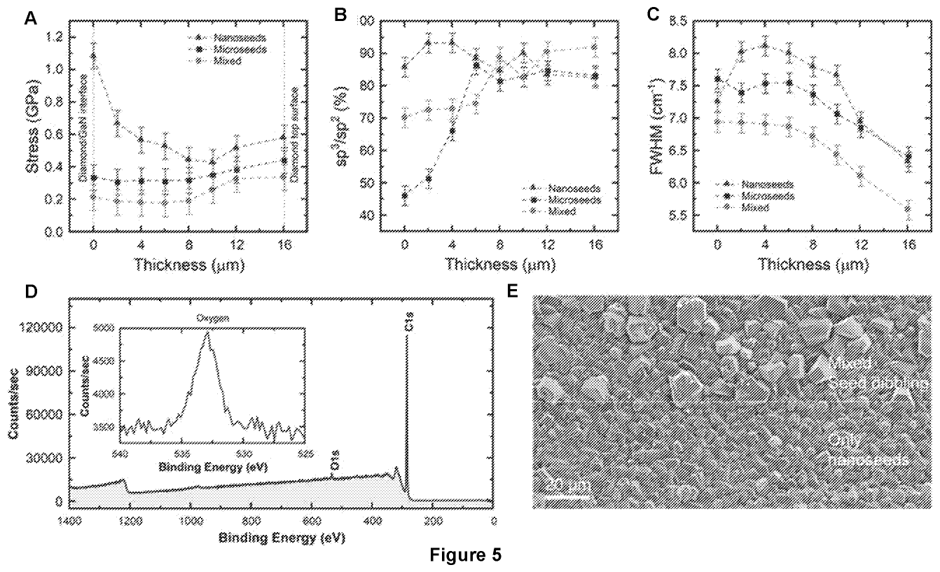

While the Raman peak of a diamond film 9 without stress is at 1332 cm^{-1 35}, it was slightly higher in all of the abovementioned samples, which corresponds to a compressive stress in the diamond 9. The stress profile was calculated based on the positive shift of the peak (FIG. 5(a))³⁶. The highest stress was measured only in the samples with nanoseeds at the interface with GaN (1.1 GPa), which is significantly lower than the typical values measured for diamond films grown at above 700° C. on GaN-on-Si membrane structures (5.6 GPa and 23.6 GPa depending on the dimensions)²⁰, which can be due to the dibbling of the substrate 3, 3A. Moving towards the top diamond surface, the stress gradually reduced to 0.6 GPa. The diamond films 9 with microseeds MS and mixed seeding showed much lower stress at the interface of 0.35 GPa and 0.2 GPa, respectively. Small variations were observed near the top surface (>12 μm thick), which can be attributed to the small changes in reactor parameters during the growth.

Such results highlight the significant benefit of seed dibbling methods combined with mixed seeding to obtain low residual stresses in the diamond, which is crucial to avoid the film delamination and cracks.

All diamond films 9 presented a high phase purity (sp³/sp² ratios), ranging between 80% to 95% at thicknesses above 8 μm, which indicates the low graphitic phases of the carbon atoms and high crystalline quality of diamond (FIG. 5(b)). Similar sp³/sp² ratio was observed in the entire thickness of the substrates with nanoseeds NS. However, at the diamond/GaN interface with the microseeds and mixed seeds, lower ratios of 45% and 70% were observed, respectively. Nevertheless, the phase purity in these films rapidly increased by increasing the thickness of the film, saturating at their highest values at thicknesses above 8 μm.

The high crystalline quality of the diamond films 9 was verified by the full width at half maximum (FWHM) of the Raman peak. The Raman spectrum of natural diamond has a FWHM of about 2 cm⁻¹, however polycrystalline CVD films generally demonstrate higher widths (between 5 to 15 cm⁻¹) depending on the amount of crystalline disorders caused by defects or strain³⁷. As shown in FIG. 5(c), the reduction of FWHM from the interface towards the top surface corresponds to higher film qualities. Mixed seeds generally showed the lowest FWHM, and thus the best crystalline quality.

X-ray photoelectron spectroscopy (XPS) spectrum in FIG. 5(d) shows a strong peak of the C1s and a very small peak related to the O1s. The analysis of the XPS spectrum revealed a very high purity of the diamond films with 98.27% carbon, 0.27% nitrogen and 1.46% oxygen that has been naturally adsorbed at the surface.

In the seed dibbling method with mixed seeds, the growth initiated by the microseeds MS resulted in much larger grains than those grown with nanoseeds NS (FIG. 5(e)). The higher average grain size is an important aspect to significantly enhance the film thermal conductivity for the same diamond thickness, due to the reduction of intra-grain thermal resistances^{3,38,39}. Due to the random orientation of the diamond grains and variations of their size, the as-grown diamond films 9 presented rough surfaces with tens-of-micron roughness (FIG. 6(a)). Such roughness is an issue for the wafer processing. Therefore, the diamond films 9 require a polishing step that was conventionally challenging because of the high residual stress and low adhesion of the diamond films deposited using conventional methods. However, here the polishing of diamond films 9 was enabled by the major improvements achieved by the seed dibbling method. The presence of large microseeds MS in the holes 7 and their attachment to the sidewalls by the nanoseeds NS resulted in the formation of diamond pillars embedded in the substrate 3, 3A (FIG. 4(b)), which can act as an anchor increasing the shear strength at the interface with the substrate 3, 3A. In addition, the low residual stresses provided excellent stability for the diamond films 9 to sustain the mechanical polishing steps (FIG. 6(b)).

After the fine polishing of the substrates 3, 3A comprising the diamond layer 9 with the lapping machine, the high-quality diamond films 9 presented transparency surfaces. The atomic force microscope (AFM) scans of the areas larger than 30 μm by 30 μm revealed sub-nanometer roughness with arithmetic roughness average (Rₐ) and root mean square roughness (R_{q}) of 0.5 nm and 0.6 nm, respectively (FIG. 6(c)). The seed dibbling method enabled a reliable growth and polishing of the diamond on AlGaN/GaN substrates with reproducible high quality (FIG. 6(d)). Neither the Raman spectrum nor the FWHM showed any changes after polishing, indicating that the high quality of diamond was preserved after the polishing (FIG. 6(d)).

A seed dibbling method was herein presented for seeding and growth of diamond on other substrates such as AlGaN/GaN-on-Si by intentional micro-structuration of the substrates 3, 3A and diamond seeding with both microseeds MS and nanoseeds NS. The configuration of the holes 7 was optimized to efficiently entrap the microseeds and to have the contribution of both seed types for the diamond growth, obtaining a full coalescence without the formation of any cavities. In addition, diamond pillars formed inside the holes 7 by the growth of the nanoseeds NS attaching the microseeds MS to the sidewalls resulted in excellent adhesion of diamond to the substrate and the high shear strength at the interface.

The material characterizations of the diamond films 9 grown using seed dibbling showed better crystallinity and larger grain size compared to the conventional nanoseeding methods. The growth method of the present disclosure resulted in high purity of the diamond film 9 with more than 98% carbon atoms and sp³/sp² ratio as high as 95%. The low residual stress of the diamond film 9 (0.2 GPa), excellent adhesion to the substrate 3, 3A and the high mechanical stability gained by seed dibbling enabled reliable and reproducible diamond growth on GaN and subsequent polishing steps to obtain smooth diamond surfaces with less than 1 nm roughness. The polished diamond-on-GaN substrates developed can be a cost-effective approach for the development of integrated heat spreaders, power integrated ICs using complementary switches, and novel heterostructure devices that combine the properties of diamond and GaN.

While the invention has been disclosed with reference to certain preferred embodiments, numerous modifications, alterations, and changes to the described embodiments, and equivalents thereof, are possible without departing from the sphere and scope of the invention. Accordingly, it is intended that the invention not be limited to the described embodiments and be given the broadest reasonable interpretation in accordance with the language of the appended claims. The features of any one of the above-described embodiments may be included in any other embodiment described herein.

### REFERENCES

(1) Koizumi, S.; Umezawa, H.; Pernot, J.; Suzuki, M. Power Electronics Device Applications of Diamond Semiconductors; Woodhead Publishing Series in Electronic and Optical Materials; Elsevier Science, 2018. https://doi.org/10.1016/c2016-0-03999-2.
(2) Amano, H.; Baines, Y.; Beam, E.; Borga, M.; Bouchet, T.; Chalker, P. R.; Charles, M.; Chen, K. J.; Chowdhury, N.; Chu, R.; De Santi, C.; De Souza, M. M.; Decoutere, S.; Di Cioccio, L.; Eckardt, B.; Egawa, T.; Fay, P.; Freedsman, J. J.; Guido, L.; Haberlen, O.; Haynes, G.; Heckel, T.; Hemakumara, D.; Houston, P.; Hu, J.; Hua, M.; Huang, Q.; Huang, A.; Jiang, S.; Kawai, H.; Kinzer, D.; Kuball, M.; Kumar, A.; Lee, K. B.; Li, X.; Marcon, D.; Marz, M.; McCarthy, R.; Meneghesso, G.; Meneghini, M.; Morvan, E.; Nakajima, A.; Narayanan, E. M. S.; Oliver, S.; Palacios, T.; Piedra, D.; Plissonnier, M.; Reddy, R.; Sun, M.; Thayne, I.; Torres, A.; Trivellin, N.; Unni, V.; Uren, M. J.; Van Hove, M.; Wallis, D. J.; Wang, J.; Xie, J.; Yagi, S.; Yang, S.; Youtsey, C.; Yu, R.; Zanoni, E.; Zeltner, S.; Zhang, Y. The 2018 GaN Power Electronics Roadmap. J. Phys. D. Appl. Phys. 2018, 51 (16), 163001. https://doi.org/10.1088/1361-6463/aaaf9d.
(3) Zhou, Y.; Ramaneti, R.; Anaya, J.; Korneychuk, S.; Derluyn, J.; Sun, H.; Pomeroy, J.; Verbeeck, J.; Haenen, K.; Kuball, M. Thermal Characterization of Polycrystalline Diamond Thin Film Heat Spreaders Grown on GaN HEMTs. Appl. Phys. Lett. 2017, 111 (4), 41901. https://doi.org/10.1063/1.4995407.
(4) Anaya, J.; Rossi, S.; Alomari, M.; Kohn, E.; T6th, L.; Pécz, B.; Hobart, K. D.; Anderson, T. J.; Feygelson, T. I.; Pate, B. B.; Kuball, M. Control of the In-Plane Thermal Conductivity of Ultra-Thin Nanocrystalline Diamond Films through the Grain and Grain Boundary Properties. Acta Mater. 2016, 103, 141-152. https://doi.org/10.1016/j.actamat.2015.09.045.
(5) Tadjer, M. J.; Anderson, T. J.; Hobart, K. D.; Feygelson, T. I.; Caldwell, J. D.; Eddy, C. R.; Kub, F. J.; Butler, J. E.; Pate, B.; Melngailis, J. Reduced Self-Heating in AlGaN/GaN HEMTs Using Nanocrystalline Diamond Heat-Spreading Films. IEEE Electron Device Lett. 2012, 33 (1), 23-25. https://doi.org/10.1109/LED.2011.2171031.
(6) Alomari, M.; Dipalo, M.; Rossi, S.; Diforte-Poisson, M. A.; Delage, S.; Carlin, J. F.; Grandjean, N.; Gaquiere, C.; Toth, L.; Pecz, B.; Kohn, E. Diamond Overgrown InAlN/GaN HEMT. Diam. Relat. Mater. 2011, 20 (4), 604-608. https://doi.org/10.1016/j.diamond.2011.01.006.
(7) Alomari, M.; Dussaigne, A.; Martin, D.; Grandjean, N.; Gaquiere, C.; Kohn, E. AlGaN/GaN HEMT on (111) Single Crystalline Diamond. Electron. Lett. 2010, 46 (4), 299. https://doi.org/10.1049/e1.2010.2937.
(8) Anderson, T. J.; Hobart, K. D.; Tadjer, M. J.; Koehler, A. D.; Imhoff, E. A.; Hite, J. K.; Feygelson, T. I.; Pate, B. B.; Eddy, C. R.; Kub, F. J. Nanocrystalline Diamond Integration with III-Nitride HEMTs. ECS J. Solid State Sci. Technol. 2017, 6 (2), Q3036-Q3039. https://doi.org/10.1149/2.0071702jss.
(9) Tadjer, M. J.; Hobart, K. D.; Feygelson, T. I.; Anderson, T. J.; Koehler, A. D.; Wang, A.; Calle, F.; Pate, B. B.; Kub, F. J.; Eddy, C. R. Diamond-Coated High Density Vias for Silicon Substrate-Side Thermal Management of GaN HEMTs.
(10) Anderson, T. J.; Hobart, K. D.; Tadjer, M. J.; Koehler, A. D.; Feygelson, T. I.; Pate, B. B.; Hite, J. K.; Kub, F. J.; Eddy, C. R. Advances in Diamond Integration for Thermal Management in GaN Power HEMTs. ECS Trans. 2014, 64 (7), 185-190. https://doi.org/10.1149/06407.0185ecst.
(11) Soleimanzadeh, R.; Khadar, R. A.; Naamoun, M.; Van Erp, R.; Matioli, E. Near-Junction Heat Spreaders for Hot Spot Thermal Management of High Power Density Electronic Devices. J. Appl. Phys. 2019, 126 (16), 165113. https://doi.org/10.1063/1.5123615.
(12) Baliga, B. J. Gallium Nitride Devices for Power Electronic Applications. Semicond. Sci. Technol. 2013, 28 (7). https://doi.org/10.1088/0268-1242/28/7/074011.
(13) Jayant Baliga, B. Wide Bandgap Semiconductor Power Devices; Elsevier, 2019. https://doi.org/10.1016/C2016-0-04021-4.
(14) Mainwood, A. Theoretical Modelling of Dopants in Diamond. J Mater Sci Mater Electron 2006, 17, 453-458. https://doi.org/10.1007/s10854-006-8091-x.
(15) Van Dreumel, G. W. G.; Tinnemans, P. T.; Van Den Heuvel, A. A. J.; Bohnen, T.; Buijnsters, J. G.; Ter Meulen, J. J.; Van Enckevort, W. J. P.; Hageman, P. R.; Vlieg, E. Realising Epitaxial Growth of GaN on (001) Diamond. J. Appl. Phys. 2011, 110 (1), 013503. https://doi.org/10.1063/1.3601351.
(16) Cheng, Z.; Mu, F.; Yates, L.; Suga, T.; Graham, S. Interfacial Thermal Conductance across Room-Temperature-Bonded GaN/Diamond Interfaces for GaN-on-Diamond Devices. ACS Appl. Mater. Interfaces 2020, 12 (7), 8376-8384. https://doi.org/10.1021/acsami.9b16959.
(17) Kawarada, H.; Yamada, T.; Xu, D.; Tsuboi, H.; Kitabayashi, Y.; Matsumura, D.; Shibata, M.; Kudo, T.; Inaba, M.; Himiwa, A. Durability-Enhanced Two-Dimensional Hole Gas of C—H Diamond Surface for Complementary Power Inverter Applications. Sci. Rep. 2017, 7. https://doi.org/10.1038/srep42368.
(18) Soleimanzadeh, R.; Naamoun, M.; Khadar, R. A.; van Erp, R.; Matioli, E. H-Terminated Polycrystalline Diamond p-Channel Transistors on GaN-on-Silicon. IEEE Electron Device Lett. 2020, 41 (1), 119-122. https://doi.org/10.1109/LED.2019.2953245.
(19) Oba, M.; Sugino, T. Oriented Growth of Diamond on (0001) Surface of Hexagonal GaN. Diam. Relat. Mater. 2001, 10 (3-7), 1343-1346. https://doi.org/10.1016/S0925-9635(00)00448-9.
(20) Cuenca, J. A.; Smith, M. D.; Field, D. E.; C-P. Massabuau, F.; Mandal, S.; Pomeroy, J.; Wallis, D. J.; Oliver, R. A.; Thayne, I.; Kuball, M.; Williams, O. A. Thermal Stress Modelling of Diamond on GaN/III-Nitride Membranes. Carbon N. Y. 2020. https://doi.org/10.1016/j.carbon.2020.11.067.
(21) Sumant, A. V; Gilbert, P. U. P. A.; Grierson, D. S.; Konicek, A. R.; Abrecht, M.; Butler, J. E.; Feygelson, T.; Rotter, S. S.; Carpick, R. W. Surface Composition, Bonding, and Morphology in the Nucleation and Growth of Ultra-Thin, High Quality Nanocrystalline Diamond Films. 2007. https://doi.org/10.1016/j.diamond.2006.12.011.
(22) May, P. W.; Tsai, H. Y.; Wang, W. N.; Smith, J. A. Deposition of CVD Diamond onto GaN. Diam. Relat. Mater. 2006, 15 (4-8), 526-530. https://doi.org/10.1016/j.diamond.2005.11.036.
(23) Field, D. E.; Cuenca, J. A.; Smith, M.; Fairclough, S. M.; Massabuau, C.-P.; Pomeroy, J. W.; Williams, O.; Oliver, R. A.; Thayne, I.; Kuball, M. Crystalline Interlayers for Reducing the Effective Thermal Boundary Resistance in GaN-on-Diamond. Cite This ACS Appl. Mater. Interfaces 2020, 12, 54145. https://doi.org/10.1021/acsami.0c10129.
(24) Zhou, Y.; Anaya, J.; Pomeroy, J.; Sun, H.; Gu, X.; Xie, A.; Beam, E.; Becker, M.; Grotjohn, T. A.; Lee, C.; Kuball, M. Barrier-Layer Optimization for Enhanced GaN-on-Diamond Device Cooling. ACS Appl. Mater. Interfaces 2017, 9 (39), 34416-34422. https://doi.org/10.1021/acsami.7b08961.
(25) Yates, L.; Anderson, J.; Gu, X.; Lee, C.; Bai, T.; Mecklenburg, M.; Aoki, T.; Goorsky, M. S.; Kuball, M.; Piner, E. L.; Graham, S. Low Thermal Boundary Resistance Interfaces for GaN-on-Diamond Devices. ACS Appl. Mater. Interfaces 2018, 10 (28), 24302-24309. https://doi.org/10.1021/acsami.8b07014.
(26) Sun, H.; Simon, R. B.; Pomeroy, J. W.; Francis, D.; Faili, F.; Twitchen, D. J.; Kuball, M. Reducing GaN-on-Diamond Interfacial Thermal Resistance for High Power Transistor Applications. Appl. Phys. Lett. 2015, 106 (11), 111906. https://doi.org/10.1063/1.4913430.
(27) Choi, S. R.; Kim, D.; Choa, S. H.; Lee, S. H.; Kim, J. K. Thermal Conductivity of AlN and SiC Thin Films. Int. J. Thermophys. 2006, 27 (3), 896-905. https://doi.org/10.1007/s10765-006-0062-1.
(28) Mallik, A. K.; Bysakh, S.; Bhar, R.; Rotter, S. Z.; Mendes, J. C. Effect of Seed Size, Suspension Recycling and Substrate Pre-Treatment on the CVD Growth of Diamond Coatings. Open J Appl. Sci. 2015, 5, 747-763. https://doi.org/10.4236/ojapps.2015.512071.
(29) Liu, D.; Francis, D.; Faili, F.; Middleton, C.; Anaya, J.; Pomeroy, J. W.; Twitchen, D. J.; Kuball, M. Impact of Diamond Seeding on the Microstructural Properties and Thermal Stability of GaN-on-Diamond Wafers for High-Power Electronic Devices. Scr. Mater. 2017, 128, 57-60. https://doi.org/10.1016/j.scriptamat.2016.10.006.
(30) Makita, H.; Nishimura, K.; Jiang, N.; Hatta, A.; Ito, T.; Hiraki, A. Ultrahigh Particle Density Seeding with Nanocrystal Diamond Particles. Thin Solid Films 1996, 281-282 (1-2), 279-281. https://doi.org/10.1016/0040-6090(96)08652-X.
(31) Smith, E. J. W.; Piracha, A. H.; Field, D.; Pomeroy, J. W.; Mackenzie, G. R.; Abdallah, Z.; Massabuau, F. C. P.; Hinz, A. M.; Wallis, D. J.; Oliver, R. A.; Kuball, M.; May, P. W. Mixed-Size Diamond Seeding for Low-Thermal-Barrier Growth of CVD Diamond onto GaN and AlN. Carbon N. Y. 2020, 167, 620-626. https://doi.org/10.1016/j.carbon.2020.05.050.
(32) May, P. W.; Tsai, H. Y.; Wang, W. N.; Smith, J. A. Deposition of CVD Diamond onto GaN. Diam. Relat. Mater. 2006, 15 (4-8), 526-530. https://doi.org/10.1016/j.diamond.2005.11.036.
(33) Tiwari, R. N.; Chang, L. Etching of GaN by Microwave Plasma of Hydrogen. Semicond. Sci. Technol. 2010, 25 (3), 035010. https://doi.org/10.1088/0268-1242/25/3/035010.
(34) Liscia, E. J. Di; Alvarez, F.; Burgos, E.; Halac, E. B.; Huck, H.; Reinoso, M. Stress Analysis on Single-Crystal Diamonds by Raman Spectroscopy 3D Mapping. Mater. Sci. Appl. 2013, 04 (03), 191-197. https://doi.org/10.4236/msa.2013.43023.
(35) Zaitsev, A. M. Optical Properties of Diamond; Springer Berlin Heidelberg: Berlin, Heidelberg, 2001; Vol. 1. https://doi.org/10.1007/978-3-662-04548-0.
(36) Liu, D.; Flewitt, P. E. J. Raman Measurements of Stress in Films and Coatings. Spectrosc. Prop. Inorg. Organomet. Compd. 2014, 45, 141-177. https://doi.org/10.1039/9781782621485-00141.
(37) Fortunato, W.; Chiquito, A. J.; Galzerani, J. C.; Moro, J. R. Crystalline Quality and Phase Purity of CVD Diamond Films Studied by Raman Spectroscopy. J. Mater. Sci. 2007, 42 (17), 7331-7336. https://doi.org/10.1007/s10853-007-1575-0.
(38) Anaya, J.; Rossi, S.; Alomari, M.; Kohn, E.; T6th, L.; Pécz, B.; Hobart, K. D.; Anderson, T. J.; Feygelson, T. I.; Pate, B. B.; Kuball, M. Control of the In-Plane Thermal Conductivity of Ultra-Thin Nanocrystalline Diamond Films through the Grain and Grain Boundary Properties. Acta Mater. 2016, 103, 141-152. https://doi.org/10.1016/j.actamat.2015.09.045.
(39) Simon, R. B.; Anaya, J.; Faili, F.; Balmer, R.; Williams, G. T.; Twitchen, D. J.; Kuball, D. M. Effect of Grain Size of Polycrystalline Diamond on Its Heat Spreading Properties. Appl. Phys. Express 2016, 9 (6). https://doi.org/10.7567/APEX.9.061302.

1-88. (canceled)

89. Diamond device or structure comprising:
at least one supporting layer or material including at least one or a plurality of support structures inside the at least one supporting layer or material;
a plurality of recesses defined by the at least one or the plurality of support structures; and
at least one diamond micro-seed and a plurality of diamond nano-seeds located in each recess or in the plurality of recesses.

90. Diamond device or structure according to claim 89, wherein the at least one or the plurality of support structures defines an opening and an upper enclosure of each recess or of the plurality of recesses, and the at least one diamond micro-seed is located inside the opening and/or the upper enclosure.

91. Diamond device or structure according to claim 90, wherein the at least one diamond micro-seed has a size or diameter that is between 40% and 95% of a size or diameter of the opening.

92. Diamond device or structure according to claim 89, wherein the at least one diamond micro-seed defines a nucleation or coalescence site for diamond crystal growth.

93. Diamond device or structure according to claim 90, wherein the opening and the upper enclosure include a plurality of distributed diamond nano-seeds, wherein the diamond nano-seeds define nucleation sites for conformal diamond growth.

94. Diamond device or structure according to claim 89, wherein each recess or the plurality of recesses is defined by at least one wall and at least one floor, and a plurality of diamond nano-seeds are located on the at least one wall and/or on the at least one floor.

95. Diamond device or structure according to claim 89, wherein each recess or the plurality of recesses has a depth, and the depth of the recess is between 60% and 1000% of a size or diameter of the at least one diamond micro-seed.

96. Diamond device or structure according to claim 89, wherein a plurality of diamond micro-seeds is located inside each recess or inside the plurality of recesses, and the diamond micro-seeds are stacked to fill each recess or the plurality of recesses.

97. Diamond device or structure according to claim 96, wherein the diamond micro-seeds are stacked to extend to an upper enclosure of each recess or the plurality of recesses.

98. Diamond device or structure according to claim 90, wherein the at least one or the plurality of support structures includes a first wall, a second wall and an upper landing extending between the first and second walls, and a plurality of diamond nano-seeds are located or distributed on the upper landing and on the first and second walls.

99. Diamond device or structure according to claim 98, wherein the least one or the plurality of support structures comprises a plurality of walls and a plurality of upper landings extending between the walls, and a plurality of diamond nano-seeds are located or distributed on the upper landings and on the walls.

100. Diamond device or structure according to claim 89, wherein the diamond nano-seeds are distributed on or attached to a surface of the at least one supporting layer or material at a density, between 10⁸ cm⁻² and 10¹⁴ cm⁻².

101. Diamond device or structure according to claim 89, wherein the recesses are located on at least one area or a plurality of areas of the at least one supporting layer or material, or the recesses are located fully across the at least one supporting layer or material.

102. Diamond device or structure according to claim 89, further including a diamond layer attached to the at least one supporting layer or material.
wherein the diamond micro-seeds are arranged inside the recesses and the diamond nano-seeds are distributed on the at least one supporting layer or material and inside the recesses to chemically bond and/or mechanically anchor or fix the diamond layer to the at least one supporting layer or material.

103. Diamond device or structure according to claim 102, wherein a lower enclosure of each recess or the plurality of recesses is diamond growth-free.

104. Diamond device or structure according to claim 89, wherein the diamond device or structure is AlN interlayer-free, SiN interlayer-free or SiC interlayer-free between the diamond layer and the at least one supporting layer or material.

105. Diamond device or structure according to claim 89, wherein the diamond device or structure includes a plurality of supporting layers or materials, and the at least one or the plurality of support structures is located inside the plurality of supporting layers or materials.

106. Diamond device or structure according to claim 89, comprising a substrate and at least one or a plurality of supporting layers or materials attached to the substrate.

107. Diamond device or structure according to claim 106, wherein the at least one or the plurality of support structures is located inside the at least one layer or the plurality of layers; or inside the at least one layer or the plurality of layers and the substrate.

108. Diamond device or structure according to claim 106, wherein the recesses extend through only the at least one or the plurality of layers attached to the substrate, or extend through the at least one or the plurality of layers attached to the substrate and into the substrate.
